(19) United States
(12) Patent Application Publication
(10) Pub. No.: US 2007/0161253 A1
(43) Pub. Date: Jul. 12, 2007

(54) METHOD OF FABRICATING A TRENCH ISOLATION LAYER IN A SEMICONDUCTOR DEVICE

(76) Inventors: Seung Soon Jang, Gyeonggi-do (KR); Yong Keon Choi, Gangwon-do (KR)

Correspondence Address: SHERR & NOURSE, PLLC, 620 HERNDON PARKWAY, SUITE 200, HERNDON, VA, 20170, US

(21) Appl. No.: 11/617,383

(22) Filed: Dec. 28, 2006

(30) Foreign Application Priority Data
Dec. 29, 2005 (KR) 10-2005-0133824

(51) Int. Cl. H01L 21/311; H01L 21/302; H01L 21/461; H01L 21/306; C23F 1/00

(52) U.S. Cl. 438/745; 438/694; 156/345.1; 156/345.11

(57) ABSTRACT

A method of fabricating a trench isolation layer in a semiconductor device. A method of fabricating a trench isolation layer in a semiconductor device, which may remove particles (e.g. in the form of an oxide layer) that are formed during a moat wet etch process.

The present application claims priority under 35 U.S.C. 119 and 35 U.S.C. 365 to Korean Patent Application No. 10-2005-0133824 (filed on Dec. 29, 2005), which is hereby incorporated by reference in its entirety.

### BACKGROUND

FIGS. 1 through 4 illustrate formation trench isolation layers in a semiconductor device. As illustrated in FIG. 1, pad oxide layer 110 and pad nitride layer 120 may be formed over semiconductor substrate 100. Semiconductor substrate may have a device isolation region and an active region.

As illustrated in FIG. 2, pad oxide layer 110 and pad nitride layer 120 may be patterned to form pad oxide layer pattern 112 and pad nitride layer pattern 122. Pad oxide layer pattern 112 and pad nitride layer pattern 122 may expose a surface of a device isolation region of semiconductor substrate 100. Device isolation region of semiconductor substrate 100 may be etched to a predetermined depth using pad oxide layer pattern 112 and pad nitride layer pattern 122 as an etch mask to form trench 130.

Sidewall oxide layer 140 may be formed in trench 130. Trench 130 may be buried with a buried insulating layer to form trench isolation layer 150. Planarization may be performed to expose an upper surface of pad nitride layer pattern 122.

As illustrated in FIG. 3, a moat wet etch process may be performed to remove pad nitride layer pattern 122. A surface of pad oxide layer pattern 122 may be exposed. Particles 160 (e.g. in the form of an oxide layer) may be formed on the exposed surface of pad oxide layer pattern 112 as the result of a moat wet etch process.

As illustrated in FIG. 4, a hard mask layer 170 may be laminated over semiconductor substrate 100, pad oxide layer 112, trench isolation layer 150, and/or particles 160. Hard mask layer 170 may include nitride layer 171 and/or TEOS oxide layer 172.

It may be desirable to remove particles 160 from pad oxide layer pattern 112. If particles 160 are not removed from pad oxide layer 112, performance of a semiconductor device may be compromised. Pad oxide layer pattern 112 may have a thickness of approximately 150 Å. Although a HF washing process may remove particles 160, this process may have limitations. Particles 160 may still remain after a HF washing process.

### SUMMARY

Embodiments relate to a method of fabricating a trench isolation layer in a semiconductor device. Embodiments relate to a method of fabricating a trench isolation layer in a semiconductor device, which may remove particles (e.g. in the form of an oxide layer) that are formed during a moat wet etch process.

Embodiments relate to a method of fabricating a trench isolation layer in a semiconductor device. A method may include at least one of: sequentially laminating a pad oxide layer and a pad nitride layer having a first thickness over a semiconductor substrate; patterning a pad oxide layer and a pad nitride layer to form a pad oxide layer pattern and a pad nitride layer pattern to expose a surface of a device isolation region of a semiconductor substrate; etching a device isolation region of a semiconductor substrate to a predetermined depth to form a trench; forming a sidewall oxide layer at an inner wall of a trench; depositing a buried insulating layer which buries a trench in which a sidewall oxide layer is formed to form a trench device isolation layer; performing a moat wet etch to remove a pad nitride layer pattern exposing a pad oxide layer pattern; wet-washing an exposed pad oxide layer pattern leaving a pad oxide layer pattern having a second thickness; and/or depositing a hard mask layer over a pad oxide layer pattern having the second thickness.

Embodiments relate to a method of fabricating a trench isolation layer in a semiconductor device. A method may include at least one of: sequentially laminating a pad oxide layer and a pad nitride layer over a semiconductor substrate; patterning a pad oxide layer and a pad nitride layer to form a pad oxide layer pattern and a pad nitride layer pattern to expose a surface of a device isolation region of a semiconductor substrate; etching a device isolation region of a semiconductor substrate to a predetermined depth to form a trench; forming a sidewall oxide layer at an inner wall of a trench; depositing a buried insulating layer for burying a trench in which a sidewall oxide layer is formed to form a trench device isolation layer; performing a moat wet etch to remove a pad nitride layer pattern exposing a pad oxide layer pattern; wet-washing an exposed pad oxide layer pattern to expose a surface of an active region in the semiconductor substrate; forming a sacrificial oxide layer at a surface of an active region in the semiconductor substrate; and/or depositing a hard mask layer over a sacrificial oxide layer and a trench device isolation layer.

Embodiments relate to a method of fabricating a trench isolation layer in a semiconductor device. A method may include at least one of: sequentially laminating a pad oxide layer and a pad nitride layer over a semiconductor substrate; patterning a pad oxide layer and a pad nitride layer to form a pad oxide layer pattern and a pad nitride layer pattern to expose a surface of a device isolation region of a semiconductor substrate; etching a device isolation region of a semiconductor substrate to a predetermined depth to form a trench; forming a sidewall oxide layer at an inner wall of the trench; depositing a buried insulating layer for burying a trench in which a sidewall oxide layer is formed to form a trench device isolation layer; performing a moat wet etch to remove a pad nitride layer pattern exposing a pad oxide layer pattern; wet-washing an exposed pad oxide layer pattern to leave a pad oxide layer pattern having a predetermined thickness; forming a TEOS oxide layer over a pad oxide layer pattern having the predetermined thickness; and/or depositing a hard mask layer on the TEOS oxide layer.

### BRIEF DESCRIPTION OF THE DRAWINGS

FIGS. 1 through 4 illustrate fabrication of a trench isolation layer.

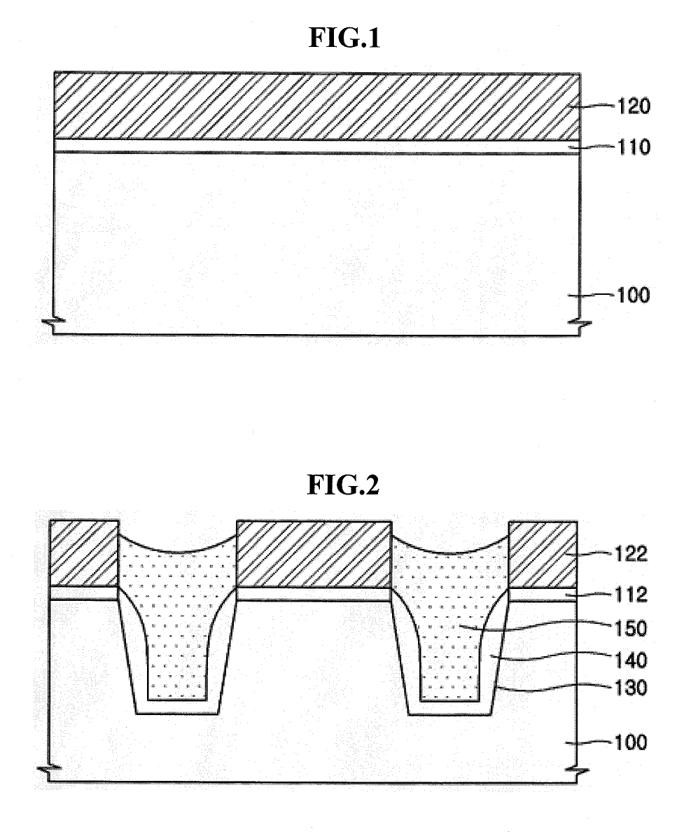

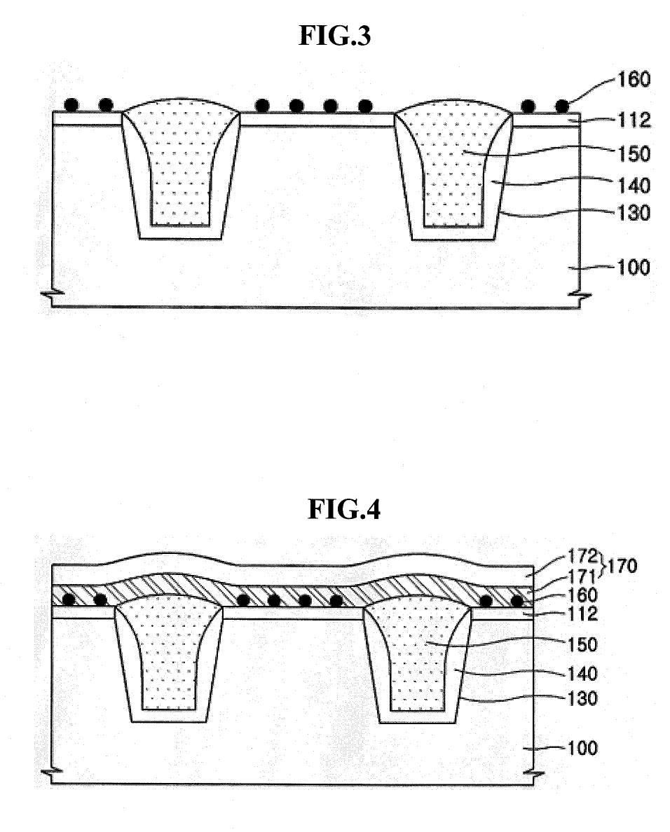

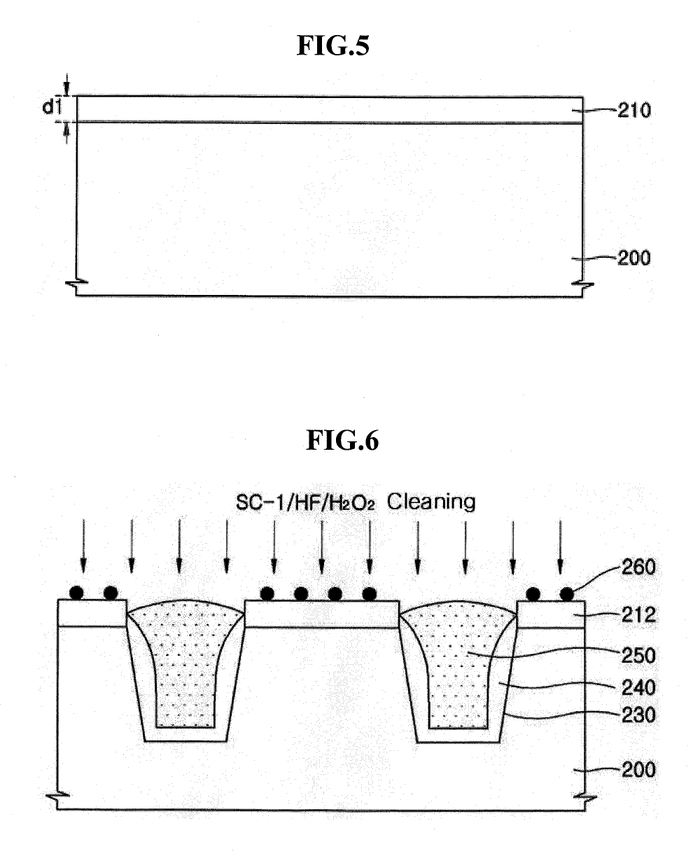

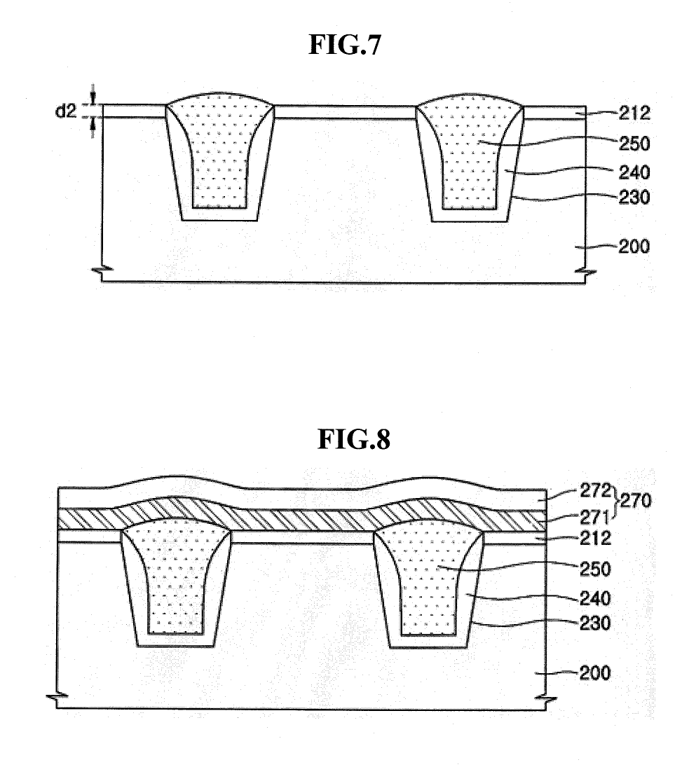

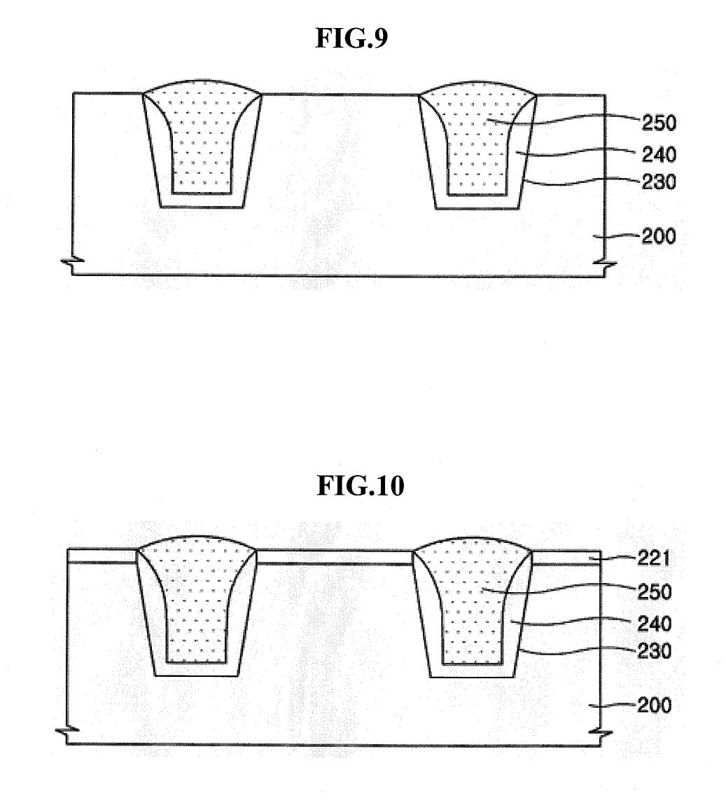

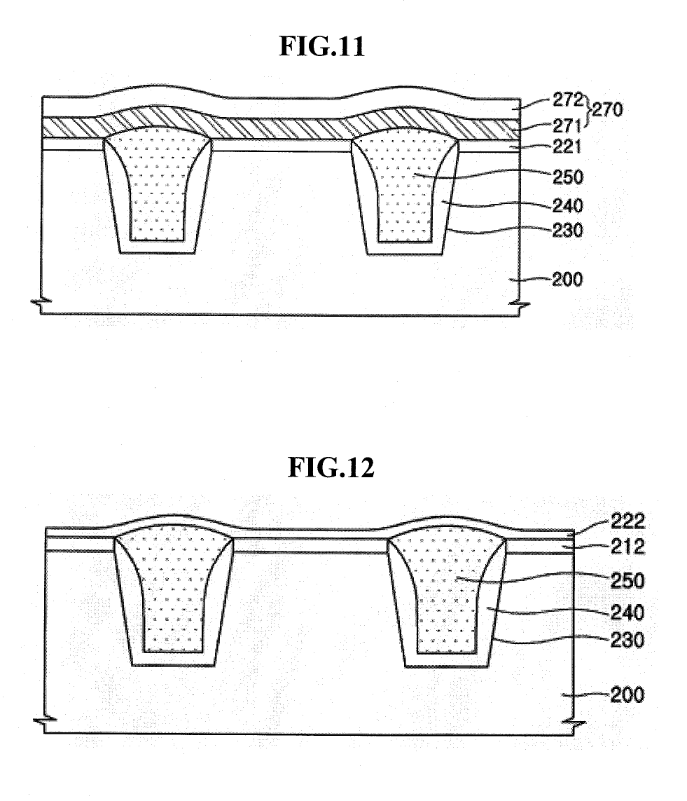

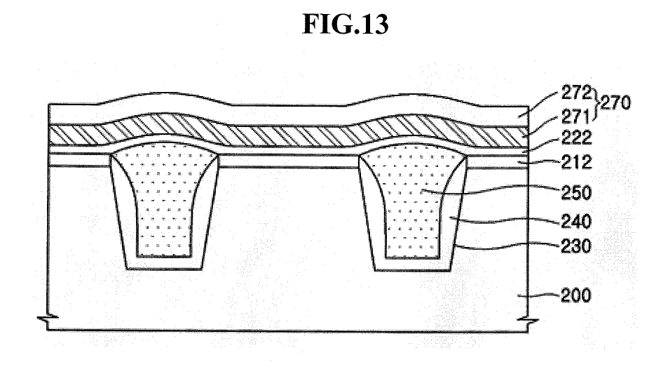

Example FIGS. 5 through 8 illustrate fabrication of a trench isolation layer, in accordance with embodiments.

Example FIGS. 9 through 11 illustrate fabrication of a trench isolation layer, in accordance with embodiments.

Example FIGS. 12 and 13 illustrate fabrication of a trench isolation layer, in accordance with embodiments.

### DETAILED DESCRIPTION

In the description of embodiment, when something is formed “on” each layer, the “on” includes the concepts of “directly and indirectly”.

Example FIGS. 5 through 8 are cross-sectional views of a trench isolation layer in a semiconductor device, according to embodiments, and a method of fabricating a trench isolation layer, in accordance with embodiments.

As illustrated in FIG. 5, pad oxide layer 210 may be formed over semiconductor substrate 200. Semiconductor substrate 200 may include a device isolation region and/or an active region. An active region may be defined by a device isolation region. A trench isolation layer may be formed at a device isolation region. Devices (e.g. a transistor) may be formed at an active region. Pad oxide layer 210 may have a first thickness d1. First thickness d1 may range from approximately 150 Åto approximately 300 Å, in accordance with embodiments. In embodiments, first thickness d1 may be relatively thick for a pad oxide layer.

As illustrated in FIG. 6, a pad nitride layer may be formed over pad oxide layer 210. Pad oxide layer 210 (FIG. 5) and pad nitride layer may be patterned to form pad oxide layer pattern 212. A pad nitride layer pattern may expose a surface of a device isolation region of semiconductor substrate 200. A device isolation region of a semiconductor substrate 200 may be etched to a predetermined depth using pad oxide layer pattern 212 and a pad nitride layer pattern as an etch mask to form trench 230. Sidewall oxide layer 240 may be formed in trench 230. Trench 230 may be buried with a buried insulating layer to form trench isolation layer 250. Planarization may be performed to expose an upper surface of a pad nitride layer pattern.

A moat wet etch process may be performed to remove a pad nitride layer pattern to expose a surface of pad oxide layer pattern 222. Particles 260 (e.g. in the form of an oxide layer) may inadvertently form on an exposed surface of pad oxide layer pattern 212 by a moat wet etch process.

In embodiments, a wet washing process may be performed on an exposed surface of pad oxide layer pattern 212 to remove particles 260. In embodiments, a wet washing process may use SC-1 washing liquor. In embodiments, a wet washing process may use HF washing liquor. In embodiments, a wet washing process may use a H₂O₂ washing liquor. In embodiments, a wet washing process may sequentially use SC-1 washing liquor, HF washing liquor, and H₂O₂ washing liquor on an exposed surface of pad oxide layer pattern 212.

As illustrated in FIG. 7, substantially all of particles 260 on a surface of pad oxide layer pattern 122 may be removed by wet washing. While removing particles 260, a predetermined thickness of pad oxide layer pattern 212 may be removed. After wet washing a reduced thickness of pad oxide layer patter 212 may be a thickness d2. Thickness d2 may be different than thickness d1. In embodiments, second thickness d2 may be less than approximately 150 Å.

As illustrated in FIG. 8, nitride layer 271 and TEOS oxide layer 272 may be sequentially laminated over the wet-washed pad oxide layer pattern 212 to form hard mask layer 270.

FIGS. 9 through 11 are cross-sectional views of a trench isolation layer in a semiconductor device, according to embodiments. FIGS. 9 through 11 illustrate methods of fabricating a trench isolation layer, according to embodiments.

As illustrated in FIG. 9, a pad oxide layer may be formed over the semiconductor substrate 200. A pad oxide layer may be substantially all removed by a wet washing process to expose a surface of an active region of semiconductor substrate 200, as illustrated in FIG. 9. In embodiments, a pad oxide layer may be formed to have a thickness of approximately 150 Å.

In embodiments, a wet washing process may use SC-1 washing liquor. In embodiments, a wet washing process may use HF washing liquor. In embodiments, a wet washing process may use a H₂O₂ washing liquor. In embodiments, a wet washing process may sequentially use SC-1 washing liquor, HF washing liquor, and H₂O₂ washing liquor on an exposed surface of a pad oxide layer pattern.

As illustrated in FIG. 10, a sacrifice oxidizing process may be performed on an exposed surface of semiconductor substrate 200 to form sacrificial oxide layer 221 in an active region of semiconductor substrate 200, in accordance with embodiments. Particles produced by a moat wet etch process may be substantially all removed by a wet washing process and a sacrifice oxidizing process, in accordance with embodiments.

As illustrated in FIG. 11, hard mask layer 270 may be sequentially laminated over the sacrificial oxide layer 221 and trench isolation layer 250. Hard mask layer 270 may include at least one of nitride layer 271 and/or TEOS oxide layer 272.

Example FIGS. 12 and 13 are cross-sectional views of a trench isolation layer in a semiconductor device, according to embodiments. Example FIGS. 12 and 13 illustrate a method of fabricating a trench isolation layer, according to embodiments.

As illustrated in FIG. 12, a pad oxide layer may be formed over semiconductor substrate 200. In embodiments, a pad oxide layer may be formed to have a thickness of approximately 150 Å. After trench isolation layer 250 has been formed, a moat wet etch process may be performed to remove a pad nitride pattern over pad oxide layer pattern 212.

In embodiments, a wet washing process may use SC-1 washing liquor. In embodiments, a wet washing process may use HF washing liquor. In embodiments, a wet washing process may use a H₂O₂ washing liquor. In embodiments, a wet washing process may sequentially use SC-1 washing liquor, HF washing liquor, and H₂O₂ washing liquor on an exposed surface of a pad oxide layer pattern 212.

A part of pad oxide layer pattern 212 may be removed so that a relatively small thickness of pad oxide layer pattern 212 remains over a surface of an active region of semiconductor substrate 200.

As illustrated in FIG. 13, hard mask layer 270 may be over on the TEOS oxide layer 222 to form a hard mask layer 270 to be used during a subsequent process. Hard mask layer 270 may include at least one of nitride layer 271 and/or TEOS oxide layer 272

Embodiments relate to a method of fabricating a trench isolation layer. In embodiments, if a pad oxide layer is formed to be relatively thick, a wet-washing may be performed to remove particles (e.g. in the form of an oxide layer). Removed particles may have been produced on a pad oxide layer pattern after a moat wet etch. A pad oxide layer may remain after a wet washing process with an adequate thickness.

In embodiments, a pad oxide layer may be formed to have a typical thickness. A pad oxide layer pattern may be completely removed by a wet etch, a part of a pad oxide layer pattern may be removed by a sacrifice oxidizing process or a wet washing, in accordance with embodiments. Particles from a moat wet etch may be removed by formation of a TEOS oxide layer.

It will be apparent to those skilled in the art that various modifications and variations can be made to embodiments. Thus, it is intended that embodiments cover modifications and variations thereof within the scope of the appended claims.

What is claimed is:

1. A method comprising:
forming a pad oxide layer pattern over a semiconductor substrate; and
removing at least a portion of the pad oxide layer pattern by a wet washing process.

2. The method of claim 1, wherein the wet washing process removes particles formed during a moat wet etch process.

3. The method of claim 2, comprising forming a pad nitride layer over the semiconductor substrate, wherein the moat wet etch process removes the pad nitride layer.

4. The method of claim 1, wherein the wet washing process comprises at least one of:
using a SC-1 washing liquor;
using a HF washing liquor; and
using a H₂O₂ washing liquor.

5. The method of claim 4, wherein the wet washing process comprises:
using the HF washing liquor after using the SC-1 washing liquor; and
using the H₂O₂ washing liquor after using the HF washing liquor.

6. The method of claim 1, wherein said removing at least a portion of the pad oxide layer comprises removing substantially all of the pad oxide layer.

7. The method of claim 6, comprising forming a sacrificial oxide layer over the semiconductor substrate.

8. The method of claim 6, wherein the pad oxide layer is formed to have a thickness of approximately 150 Å.

9. The method of claim 1, wherein the pad oxide layer is formed to have a thickness between approximately 150 Å and approximately 300 Å.

10. The method of claim 1, comprising forming a hard mask over the semiconductor substrate.

11. An apparatus comprising a pad oxide layer pattern formed over a semiconductor substrate, wherein at least a portion of the pad oxide layer pattern was removed by a wet washing process.

12. The apparatus of claim 11, wherein the wet washing process removes particles formed during a moat wet etch process.

13. The apparatus of claim 12, comprising a pad nitride layer formed over the semiconductor substrate, wherein the moat wet etch process removes the pad nitride layer.

14. The apparatus of claim 11, wherein the wet washing process comprises at least one of:
using a SC-1 washing liquor;
using a HF washing liquor; and
using a H₂O₂washing liquor.

15. The apparatus of claim 14, wherein the wet washing process comprises:
using the HF washing liquor after using the SC-1 washing liquor; and
using the H₂O₂ washing liquor after using the HF washing liquor.

16. The apparatus of claim 11, wherein substantially of the pad oxide layer pattern was removed by the wet washing process.

17. The apparatus of claim 16, comprising a sacrificial oxide layer formed over the semiconductor substrate.

18. The apparatus of claim 16, wherein the pad oxide layer is formed to have a thickness of approximately 150 Å.

19. The apparatus of claim 11, wherein the pad oxide layer is formed to have a thickness between approximately 150 Å and approximately 300 Å.

20. The apparatus of claim 11, comprising a hard formed over the semiconductor substrate.
